(19) United States
(12) Patent Application Publication
(10) Pub. No.: US 2026/0372109 A1
(43) Pub. Date: Nov. 19, 2026

(54) METHODS OF FORMING PACKAGE STRUCTURE

(71) Applicant: Taiwan Semiconductor Manufacturing Company, Ltd., Hsinchu (TW)

(72) Inventor: Wen-Shiang LIAO, Miaoli County (TW)

(73) Assignee: Taiwan Semiconductor Manufacturing Company, Ltd., Hsinchu (TW)

(21) Appl. No.: 19/754,346

(22) Filed: Jul. 27, 2026

Related U.S. Application Data
(62) Division of application No. 18/493,981, filed on Oct. 25, 2023.

(51) Int. Cl. H10W 44/00; H10D 1/20; H10W 70/685; H10W 74/01; H10W 74/10; H10W 90/00

(52) U.S. Cl. CPC H10W 44/501; H10D 1/20; H10W 70/685; H10W 74/016; H10W 74/111; H10W 90/00; H10W 90/734; H10W 90/794

(57) ABSTRACT

A method of forming a package structure includes forming a first conductive feature in a first insulating layer, and forming a second insulating layer on the first insulating layer. The second insulating layer covers the first conductive feature. The method includes disposing a magnetic element on the second insulating layer. The magnetic element includes a plurality of dielectric layers and a plurality of magnetic permeable layers, and the dielectric layers and the magnetic permeable layers are alternatively stacked. The method includes forming a molding material covering the magnetic element, and a plurality of conductive vias penetrate the second insulating layer and the molding material. The method includes forming a second conductive feature in a third insulating layer on the molding material. The first conductive feature, the conductive vias, and the second conductive feature are electrically connected to form a coil surrounding the magnetic element.

### CROSS REFERENCE TO RELATED APPLICATIONS

This application is a divisional of pending U.S. patent application Ser. No. 18/493,981, filed Oct. 25, 2023, the entirety of which is incorporated by reference herein.

### BACKGROUND

The semiconductor industry continues to improve the integration density of various electronic components (e.g., transistors, diodes, resistors, capacitors, etc.) by continual reductions in minimum feature size, which allow more components to be integrated into a given area. The individual dies are typically packaged separately. A package not only provides protection for semiconductor devices from environmental contaminants, but also provides a connection interface for the semiconductor devices packaged therein.

Three-dimensional integrated circuits (3DICs) are a recent development in semiconductor packaging in which multiple semiconductor dies are stacked upon one another, using package-on-package (PoP) and system-in-package (SiP) packaging techniques. Some 3DICs are prepared by placing dies over dies on a semiconductor wafer level. 3DICs provide improved integration density and other advantages, such as faster speeds and higher bandwidth, because of the decreased length of interconnects between the stacked dies, for example. However, there are many challenges related to 3DICs.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1T are cross-sectional views illustrating various stages of forming a package structure in accordance with some embodiments of the present disclosure.

FIG. 2 is a cross-sectional view illustrating the package structure in accordance with some embodiments of the present disclosure.

FIG. 3 is a schematic top view illustrating the package structure in accordance with some embodiments of the present disclosure.

FIG. 4 is a schematic top view illustrating the package structure in accordance with some embodiments of the present disclosure.

FIG. 5 is a schematic top view illustrating the package structure in accordance with some embodiments of the present disclosure.

FIG. 6 is a schematic top view illustrating the package structure in accordance with some embodiments of the present disclosure.

FIG. 7 is a cross-sectional view illustrating the magnetic element in accordance with some embodiments of the present disclosure.

FIG. 8 is a schematic plan view illustrating the magnetic element and the coil in accordance with some embodiments of the present disclosure.

FIG. 9 is a schematic plan view illustrating the magnetic element and the coil in accordance with some embodiments of the present disclosure.

FIG. 10A-10B are schematic plan views illustrating the package structure in accordance with some embodiments of the present disclosure.

FIG. 11 is a schematic view illustrating an apparatus for forming the magnetic permeable layer the magnetic permeable layer in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of package structures and method for forming the same are provided. The package structure includes inductors formed by magnetic elements each surrounded by a coil. The inductors formed by the magnetic elements and the coils are embedded in the molding material along with the package component, which is compatible with the current package process, and therefore reducing the time and cost of the overall process. Furthermore, the magnetic element includes a plurality of magnetic permeable layers that are separated from each other by dielectric layers. Accordingly, eddy current induced by the inductor may be reduced, improving the performance of the inductor.

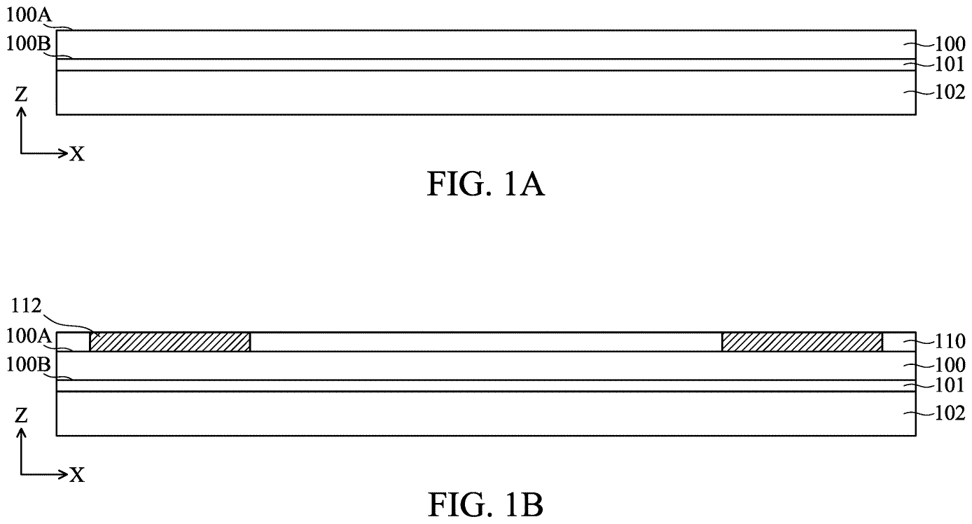

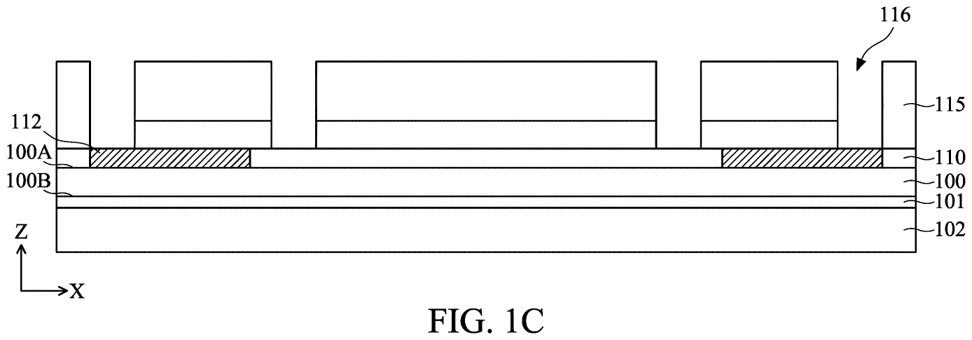

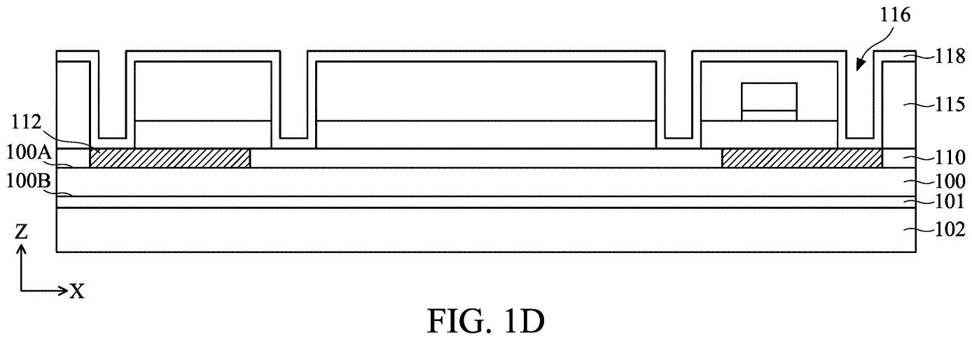

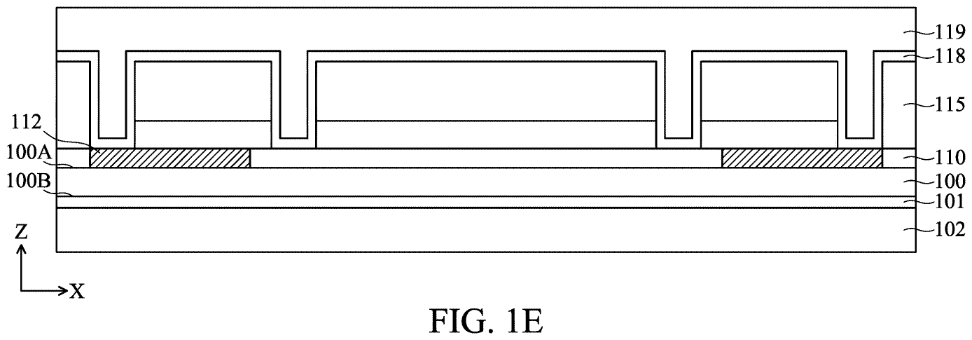

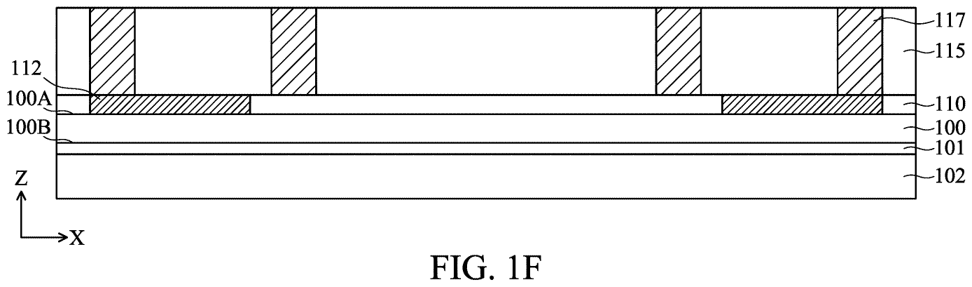

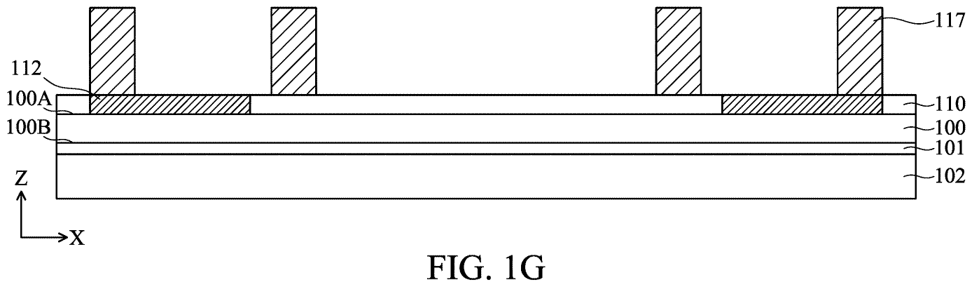

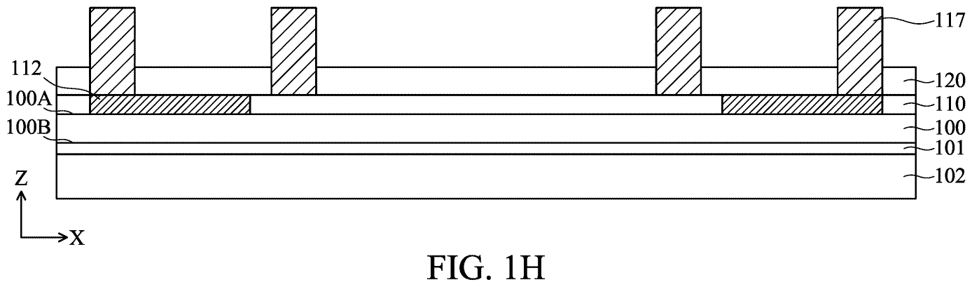

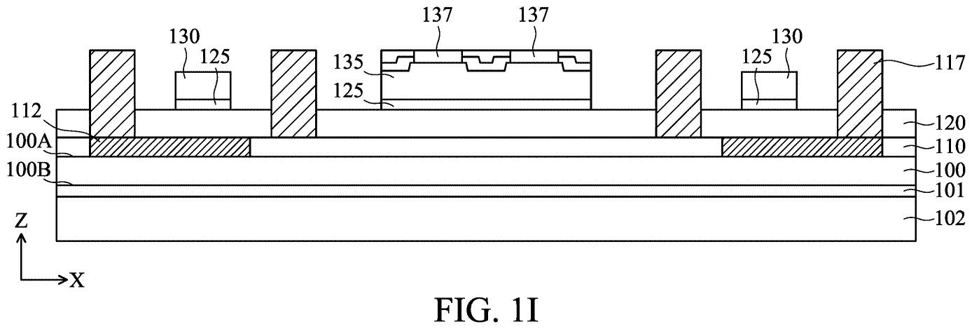

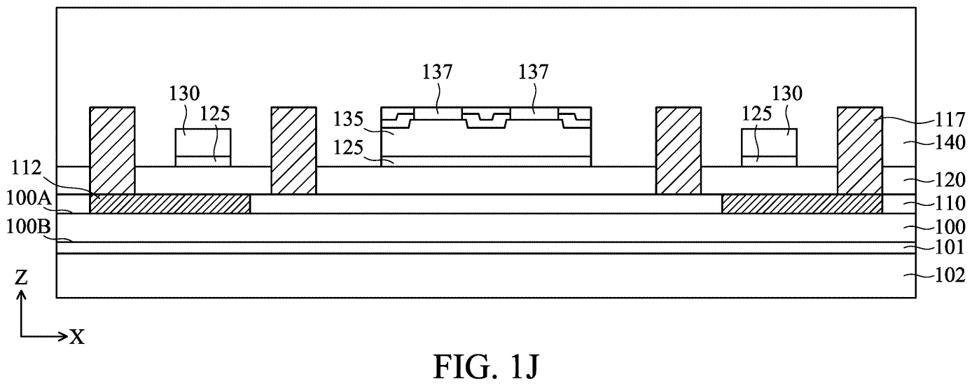

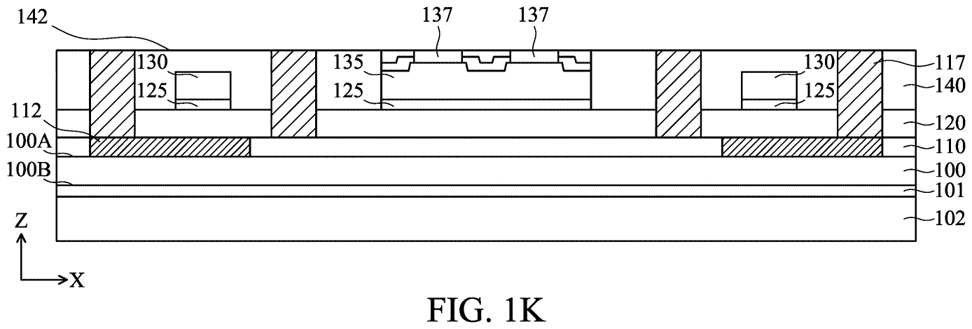

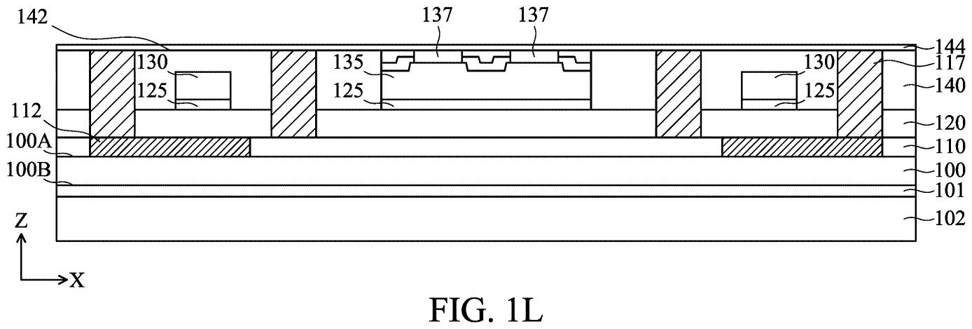

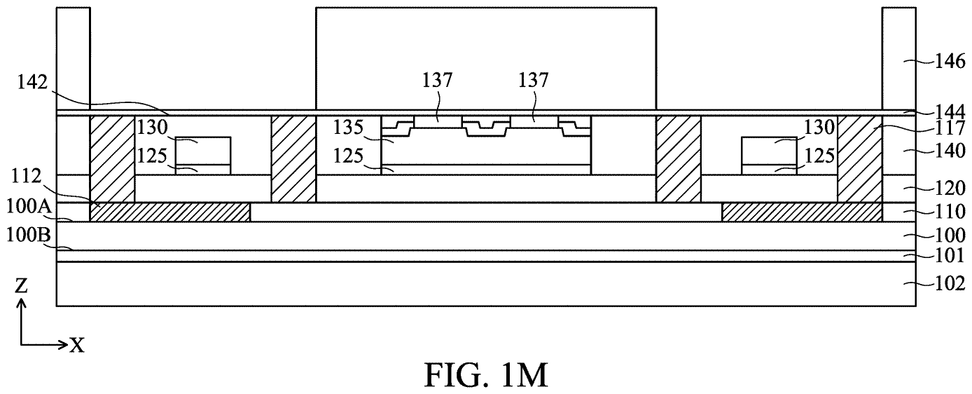

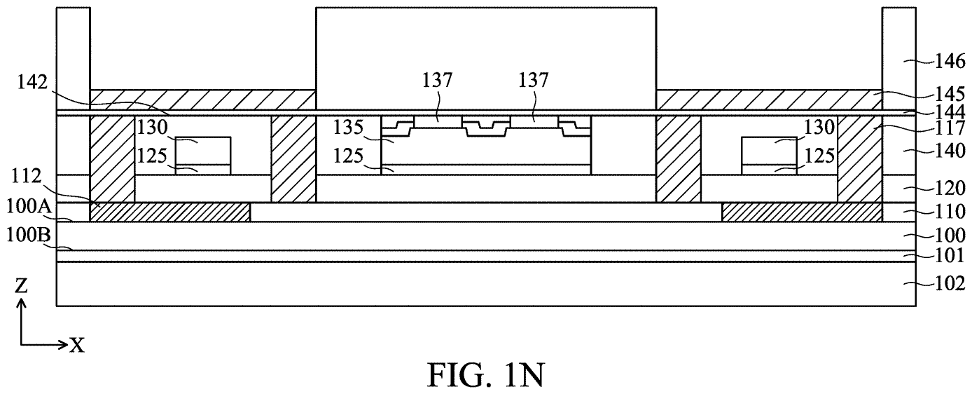

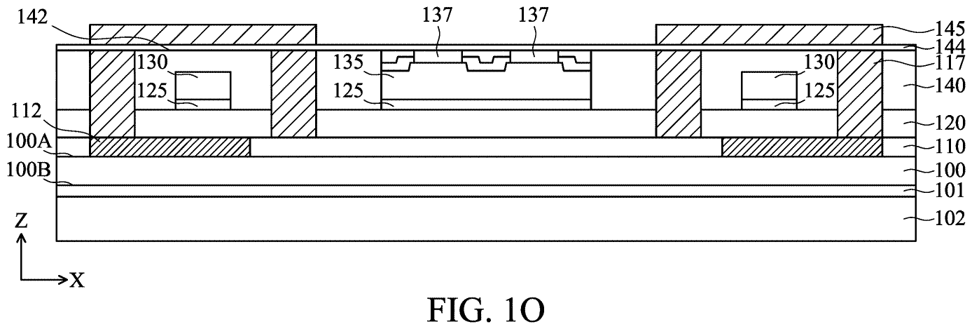

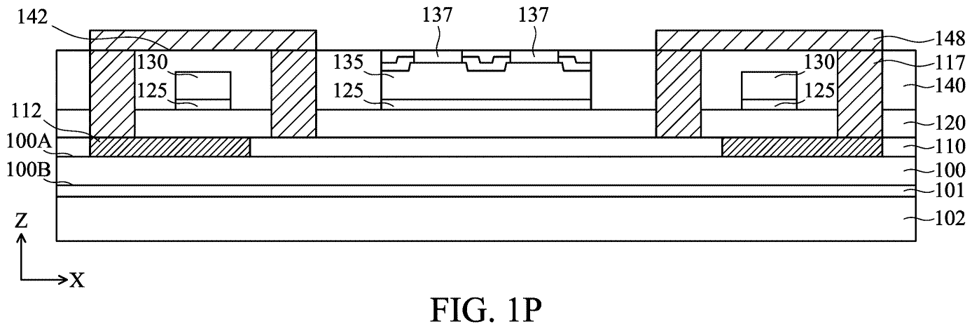

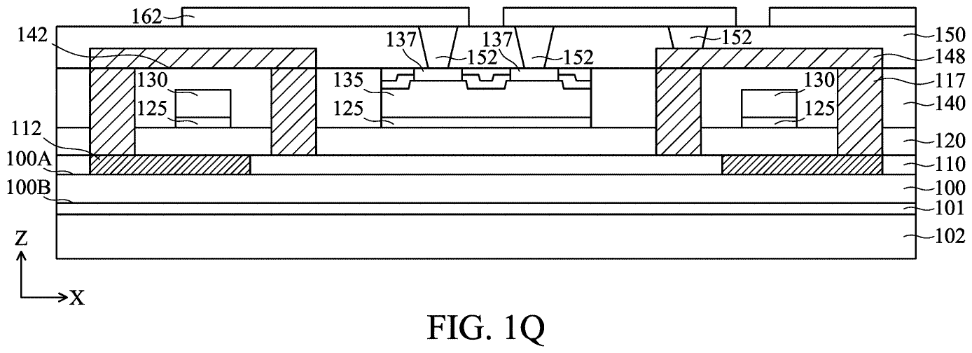

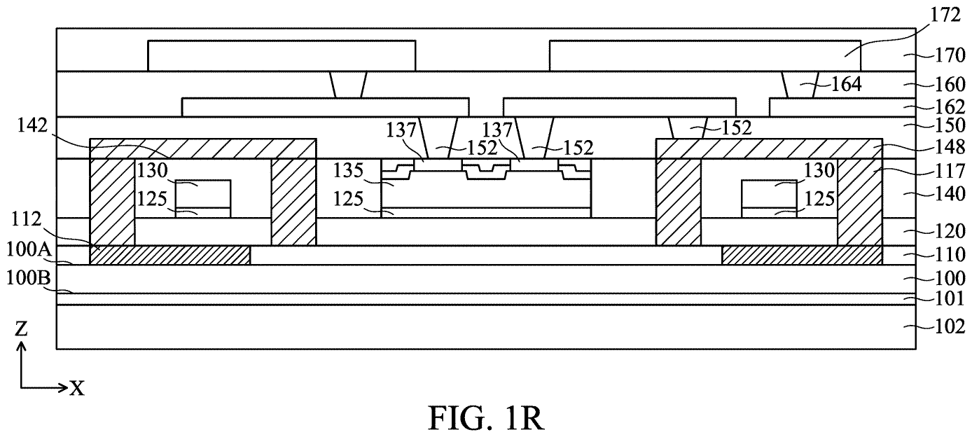

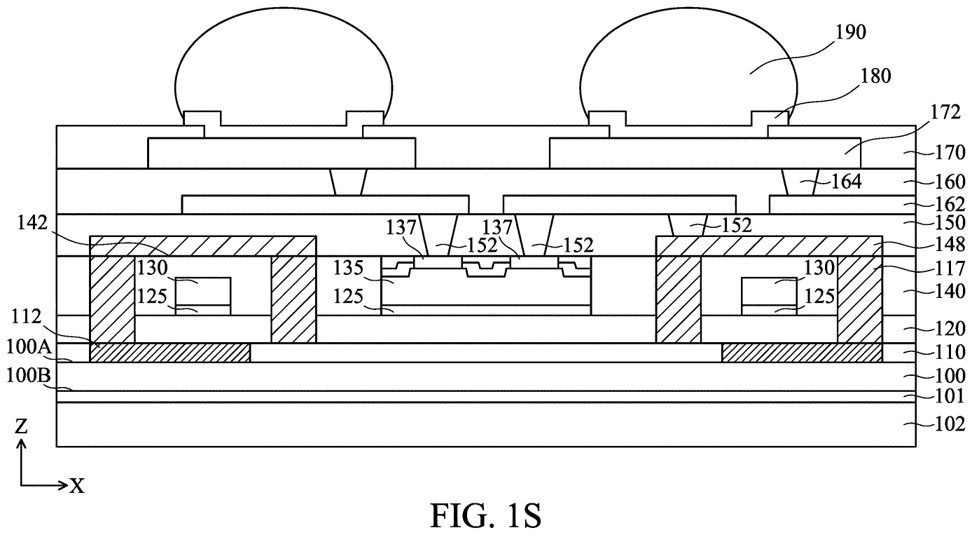

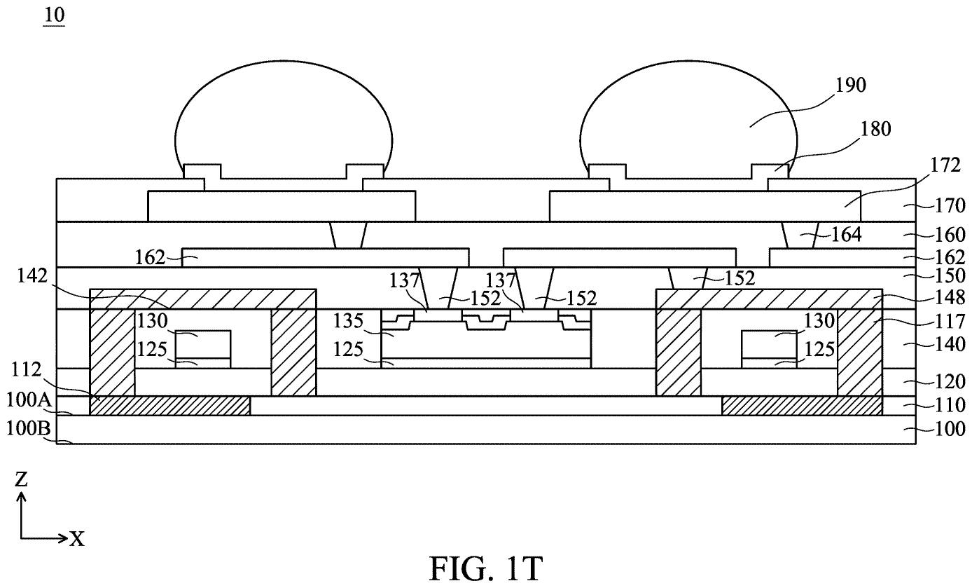

FIGS. 1A-1T are cross-sectional views illustrating various stages of forming a package structure 10 in accordance with some embodiments of the present disclosure. For example, a substrate 100 includes an organic substrate. In some embodiments, the substrate 100 is made of polymers such as polybenzoxazoles (PBO), polyimide (PI), benzocyclobutene (BCB), or the like. However, the present disclosure is not limited thereto. In some embodiments, the substrate 100 includes a semiconductor substrate, including such as silicon, doped or undoped, or an active layer of a semiconductor-on-insulator (SOI) substrate. In some embodiments, the first package component 100 includes other semiconductor materials, such as germanium; a compound semiconductor including silicon carbide, gallium arsenic, gallium phosphide, indium phosphide, indium arsenide, and indium antimonide; an alloy semiconductor including SiGe, GaAsP, AlInAs, AlGaAs, GaInAs, GaInP, and GaInAsP; or a combination thereof. Other substrates, such as multi-layered or gradient substrates, may also be used.

In addition, a carrier substrate 102 is bonded to a bottom surface 100B of the substrate 100 via a release layer 101. The carrier substrate 102 may be a glass carrier substrate, a ceramic carrier substrate, a wafer (e.g., a silicon wafer), or the like. The carrier substrate 102 may provide structural support during subsequent processing steps and in the completed structure. For example, the release layer 101 may be a light-to-heat-conversion (LTHC) coating layer. However, the present disclosure is not limited thereto.

Next, as shown in FIG. 1B, a first insulating layer 110 is formed over a top surface 100A of the substrate 100. In some embodiments, the first insulating layer 110 includes polymers such as polybenzoxazoles (PBO), polyimide (PI), benzocyclobutene (BCB), or the like. The first insulating layer 110 may be formed, for example, by spin-on coating, chemical vapor deposition (CVD), physical vapor deposition (PVD) or other suitable deposition technique. However, the present disclosure is not limited thereto. In some other embodiments, the first insulating layer 110 includes dielectric materials, such as phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a plurality of conductive features 112 are formed in the first insulating layer 110. The conductive features 112 may include conductive materials. The conductive materials may include metal such as copper, aluminum, nickel, titanium, a combination thereof or other suitable metals.

Afterwards, as shown in FIG. 1C, a patterned photoresist layer 115 is formed over the first insulating layer 110. The patterned photoresist layer 115 may be formed by a deposition process and a patterning process. The deposition process for forming the patterned photoresist layer 115 may include a chemical vapor deposition (CVD) process, a high-density plasma chemical vapor deposition (HDPCVD) process, a spin-on process, a sputtering process, or another applicable process. The patterning process for forming the patterned photoresist layer may include a photolithography process and an etching process. The photolithography process may include photoresist coating (e.g., spin-on coating), soft baking, mask aligning, exposure, post-exposure baking, developing the photoresist, rinsing, and drying (e.g., hard baking). The etching process may include a dry etching process or a wet etching process.

In some embodiments, a plurality of the trenches 116 are formed in the patterned photoresist layer 115. That is, the trenches 116 are separated from each other by a part of the patterned photoresist layer 115. At this stage, the part of the patterned photoresist layer 115 is sandwiched between the adjacent trenches 116 in a horizontal direction (for example, parallel to the X axis). At least one of the trenches 116 partially exposes one of the underlying conductive features 112, which means that the trenches 116 penetrate the patterned photoresist layer 115 and expose the underlying first package component 100. In some embodiments, the trenches 116 has a height less than about 300μm. However, the present disclosure is not limited thereto. In some embodiments, the first trenches 115 are formed to have the same width in the direction parallel to the X-Y plane. However, the present disclosure is not limited thereto.

Then, as shown in FIG. 1D, a seeding layer 118 is formed on the patterned photoresist layer 115 and in the trenches 116. In some embodiments, the seeding layer 118 is conformally deposited on the patterned photoresist layer 115 and in the trenches 116. For example, the thickness of the seeding layer 118 is ranged from about 1 kÅ to about 5 kÅ in the direction (e.g. the Z direction) perpendicular to the X-Y plane. However, the present disclosure is not limited thereto. In some embodiments, the seeding layer 118 may include copper, nickel, tin, or an alloy thereof. However, the present disclosure is not limited thereto.

Next, as shown in FIG. 1E, a conductive material 119 is deposited over the seeding layer 118. In some embodiments, the conductive material 119 is formed on the patterned photoresist layer 115 and in the trenches 116. In some embodiments, the trenches 116 are overfilled by the seeding layer 118 and the conductive material 119. For example, the conductive material 119 may be formed by performing a plating process on the seeding layer 118. The plating process may include, for example, an electrochemical plating (ECP) process or an electroless metal plating process. Other suitable processes are within the contemplated scope of disclosure. The conductive material 119 may include metal such as copper, aluminum, nickel, titanium, a combination thereof or other suitable metals.

As shown in FIG. 1F, a planarization process (such as, chemical mechanical polish (CMP) or any other suitable planarization process) is performed on the seeding layer 118 and the conductive material 119. To be more specific, the part of the seeding layer 118 and the conductive material 119 over the top surface of the patterned photoresist layer 115 is removed, forming a plurality of conductive vias 117 in the trenches 116 of the patterned photoresist layer 115. After the planarization process is completed, the top surface of the conductive vias 117 may be substantially coplanar with the top surface of the patterned photoresist layer 115.

As shown in FIG. 1G, the patterned photoresist layer 115 is removed. In some embodiments, the patterned photoresist layer 115 may be subsequently removed by ashing, dissolving the photoresist mask or by consuming the photoresist mask during the etch process. For example, the etching process may be a dry etching process or a wet etching process. In some embodiments, the dry etching process includes using a fluorine-based etchant gas, such as SF₆, CₓF_{y}, NF₃ or a combination thereof. The etching process may be a time-controlled process. As a result, the first conductive features 112 are exposed.

Next, as shown in FIG. 1H, a second insulating layer 120 is formed over the first insulating layer 110. In some embodiments, the second insulating layer 120 includes polymers such as polybenzoxazoles (PBO), polyimide (PI), benzocyclobutene (BCB), or the like. The second insulating layer 120 may be formed, for example, by spin-on coating, chemical vapor deposition (CVD), physical vapor deposition (PVD) or other suitable deposition technique. However, the present disclosure is not limited thereto. In some other embodiments, the second insulating layer 120 includes dielectric materials, such as phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, the second insulating layer 120 may be formed by the same material and the same method as the first insulating layer 110. However, the present disclosure is not limited thereto. In some embodiments, the second insulating layer 120 is formed by using material or method that is different from that of the first insulating layer 110.

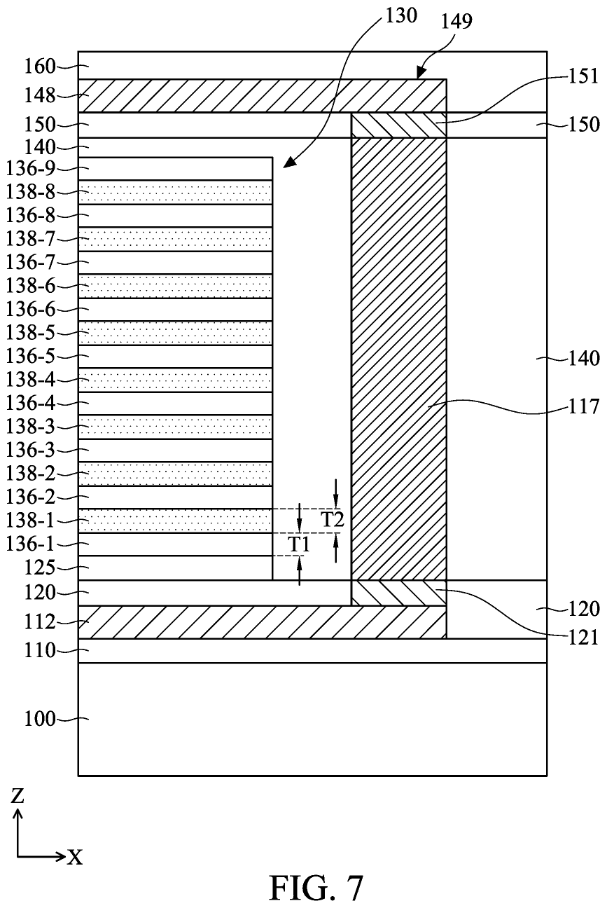

Next, as shown in FIG. 1I, a plurality of magnetic elements 130 are disposed on the second insulating layer 120. In some embodiments, each of the magnetic elements 130 is bonded to the second insulating layer 120 via an attach film 125. For example, the attach film 125 is formed on the second insulating layer 120 for the subsequent bonding process. For example, the material of the attach film 125 includes SiON, SiO₂, any other suitable material, or a combination thereof. However, the present disclosure is not limited thereto. In some embodiments, the magnetic element 130 includes a plurality of dielectric layers and a plurality of magnetic permeable layers (not individually shown in the present embodiments), and the dielectric layers and the magnetic permeable layers are alternatively stacked. The detail structure of the magnetic element 130 is further discussed below in accompany with FIG. 7.

Meanwhile, a package component 135 is disposed on the second insulating layer 120. In some embodiments, the package component 135 is bonded to the second insulating layer 120 via the attach film 125. In some embodiments, the magnetic elements 130 and the package component 135 are disposed on the second insulating layer 120 at the same step (for example, during the same bonding process). For example, the package component 135 may be a device die, a package with a device die(s) packaged therein, a System-on-Chip (SoC) die including a plurality of device dies packaged as a system, or the like. The package component 135 may be or may comprise logic dies, memory dies, input-output dies, Integrated Passive Devices (IPDs), or the like, or combinations thereof. For example, the logic device dies in the package component 135 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies in the package component 135 may include Static Random Access Memory (SRAM) dies, Dynamic Random Access Memory (DRAM) dies, or the like. The package component 135 may include semiconductor substrates and interconnect structures, which are not individually shown in the present embodiment. In some embodiments, a plurality of bonding pads 137 are formed on the package component 135. For example, the bonding pads 137 include conductive material such as tungsten (W), cobalt (Co), nickel (Ni), copper (Cu), silver (Ag), gold (Au), aluminum (Al), any other suitable conductive material, or a combination thereof.

Then, as shown in FIG. 1J, a molding material 140 is formed over the conductive vias 117, the magnetic elements 130 and the package component 135. That is, the molding material 140 may encapsulate (i.e. cover) the semiconductor dies the conductive vias 117, the magnetic elements 130 and the package component 135 in the vertical direction (e.g. the Z direction) and in the horizontal direction (e.g. the X/Y direction). For example, the molding material 140 may include an epoxy polymer material (e.g., an epoxy molding compound (EMC). The molding material 140 may be formed, for example, by a deposition process such as CVD, PECVD, PVD, spin coating, lamination or other suitable deposition technique. In some embodiments, the molding material 140 is deposited to have a thickness greater than 50 μm. However, the present disclosure is not limited thereto.

As, as shown in FIG. 1K, a planarization process may be performed on the upper surface of the molding material 140 until the upper surfaces of the conductive vias 117 (or the upper surface of the bonding pads 137 of the package component 135) are exposed. In some embodiments, the upper surface 142 of the molding material 140 is substantially coplanar with the upper surfaces of the conductive vias 117 (or the upper surface of the bonding pads 137 of the package component 135). The planarization process may include, for example, a mechanical grinding process and/or a CMP process. In some embodiments, after the above planarization process is completed, the upper surfaces of the magnetic elements 130 are still covered by the molding material 140, which ensures the magnetic elements 130 are electrically isolated from other components.

Then, as shown in FIG. 1L, a seeding layer 144 is formed on the upper surface 142 of the molding material 140 and in contact with the upper surfaces of the conductive vias 117 (and/or the upper surface of the bonding pads 137 of the package component 135). In some embodiments, the seeding layer 144 is conformally deposited on the molding material 140, the conductive vias 117, and the package component 135. For example, the thickness of the seeding layer 144 is ranged from about 0.5 kÅ to about 3 kÅ in the direction (e.g. the Z direction) perpendicular to the X-Y plane. In some embodiments, the thickness of the seeding layer 144 is different from the thickness of the seeding layer 118. For example, the seeding layer 144 may be thinner than the seeding layer 118. However, the present disclosure is not limited thereto. In some embodiments, the seeding layer 144 may include copper, nickel, tin, or an alloy thereof. However, the present disclosure is not limited thereto.

Next, as shown in FIG. 1M, a patterned photoresist layer 146 is formed over the seeding layer 144. The patterned photoresist layer 146 may be formed by a deposition process and a patterning process. The deposition process for forming the patterned photoresist layer 146 may include a chemical vapor deposition (CVD) process, a high-density plasma chemical vapor deposition (HDPCVD) process, a spin-on process, a sputtering process, or another applicable process. The patterning process for forming the patterned photoresist layer may include a photolithography process and an etching process. The photolithography process may include photoresist coating (e.g., spin-on coating), soft baking, mask aligning, exposure, post-exposure baking, developing the photoresist, rinsing, and drying (e.g., hard baking). The etching process may include a dry etching process or a wet etching process. In some embodiments, the patterned photoresist layer 146 partially covers the seeding layer 144, and therefore the patterned photoresist layer 146 overlaps the package component 135 and does not overlap the conductive vias 117 in the vertical direction (e.g. the Z direction) which perpendicular to the X-Y plane.

Then, as shown in FIG. 1N, a conductive material 145 is deposited over the part of the seeding layer 144, which is exposed from the patterned photoresist layer 146. In some embodiments, the conductive material 145 is formed in the trenches of the patterned photoresist layer 146. For example, the conductive material 145 may be formed by performing a plating process on the seeding layer 144. The plating process may include, for example, an electrochemical plating (ECP) process or an electroless metal plating process. Other suitable processes are within the contemplated scope of disclosure. The conductive material 145 may include metal such as copper, aluminum, nickel, titanium, a combination thereof or other suitable metals.

As shown in FIG. 1°, the patterned photoresist layer 146 is removed. In some embodiments, the patterned photoresist layer 146 is removed by a wet etching process. To be more specific, the wet process includes applying a solution to remove patterned photoresist layer 146. For example, the solution may include dimethylsufoxide (DMSO), water (H₂O), tetramethyl ammonium hydroxide (TMAH), or the like. However, the present disclosure is not limited thereto. In some embodiments, the patterned photoresist layer 146 may be subsequently removed by ashing, dissolving the photoresist mask or by consuming the photoresist mask during the etch process. For example, the etching process may be a dry etching process or a wet etching process. In some embodiments, the dry etching process includes using a fluorine-based etchant gas, such as SF₆, CₓF_{y}, NF₃ or a combination thereof. The etching process may be a time-controlled process.

Next, as shown in FIG. 1P, an etching process (such as, a dry etching process or a wet etching process) is performed on the part of the seeding layer 144 which is not covered by the conductive material 145. To be more specific, the part of the seeding layer 144 is remove to expose the top surface of the bonding pads 137 of the package component 135. For example, the etching process includes using an etching solution, such as hydrogen fluoride (HF), copper/NH₃ mixture, TMAH-containing solution, or a combination thereof. As a result, the conductive material 145 and the underlying seeding layer 144 remain over the molding material 140. It should be noted that for the sake of brevity, the conductive material 145 and the underlying seeding layer 144 are referred to as the conductive features 148 in the following paragraphs, and the conductive features 148 are shown to represent the conductive material 145 and the underlying seeding layer 144 in the following drawings.

It is noted that the conductive features 148 are electrically connected to the conductive vias 117 and the conductive features 112, so as to form a coil that surrounds the corresponding magnetic element 130. Accordingly, a plurality of inductors may be formed for enhancing the performance of the devices in the resulting package structure. In some embodiments, the top surface of the conductive features 148 is higher than the top surface of the package component 135, and the bottom surface of the conductive feature 112 is lower than the bottom surface of the package component 135. The resulted inductors operate along with the package component 135 in the package structure so as to reduce signal interference or stabilize the voltage of the package component 135. In addition, the inductor formed by the magnetic element 130 and the coil is embedded in the molding material 140 along with the package component 135. As a result, the arrangement of the magnetic element 130 is compatible with the current package process, and therefore reducing the time and cost of the overall process.

Then, as shown in FIG. 1Q, a third insulating layer 150 is formed over the conductive features 148 and the package component 135. In some embodiments, the third insulating layer 150 includes polymers such as polybenzoxazoles (PBO), polyimide (PI), benzocyclobutene (BCB), or the like. The third insulating layer 150 may be formed, for example, by spin-on coating, chemical vapor deposition (CVD), physical vapor deposition (PVD) or other suitable deposition technique. However, the present disclosure is not limited thereto. In some other embodiments, the third insulating layer 150 includes dielectric materials, such as phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, the third insulating layer 150 may be formed by the same material and the same method as the first insulating layer 110 or the second insulating layer 120. However, the present disclosure is not limited thereto. In some embodiments, the third insulating layer 150 is formed by using material or method that is different from that of the first insulating layer 110 or the second insulating layer 120.

In addition, in some embodiments, a plurality of conductive features 152 are formed in the third insulating layer 150. The conductive features 152 may include conductive materials. The conductive materials may include metal such as copper, aluminum, nickel, titanium, a combination thereof or other suitable metals. In some embodiments, the bonding pads 137 are each aligned with the conductive features 152 over the package component 135 to form electrical connection between the package component 135 and the external environment. In some embodiments, the conductive features 152 are electrically connected to the conductive features 148.

Furthermore, a redistribution layer 162 is formed over the third insulating layer 150. The redistribution layer 162 may include conductive materials. The conductive materials may include metal such as copper, aluminum, nickel, titanium, a combination thereof or other suitable metals. In some embodiments, the redistribution layer 162 is electrically connected to the conductive features 152 to form electrical connection between the package component 135 and the external environment.

As shown in FIG. 1R, a fourth insulating layer 160 is formed over the redistribution layer 162 and the third insulating layer 150. In some embodiments, the fourth insulating layer 160 includes polymers such as polybenzoxazoles (PBO), polyimide (PI), benzocyclobutene (BCB), or the like. The fourth insulating layer 160 may be formed, for example, by spin-on coating, chemical vapor deposition (CVD), physical vapor deposition (PVD) or other suitable deposition technique. However, the present disclosure is not limited thereto. In some other embodiments, the fourth insulating layer 160 includes dielectric materials, such as phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, the fourth insulating layer 160 may be formed by the same material and the same method as the first insulating layer 110, the second insulating layer 120, or the third insulating layer 150. However, the present disclosure is not limited thereto. In some embodiments, the fourth insulating layer 160 is formed by using material or method that is different from that of the first insulating layer 110 or the second insulating layer 120,

### Or the Third Insulating Layer 150.

In addition, in some embodiments, a plurality of conductive features 164 are formed in the fourth insulating layer 160. The conductive features 164 may include conductive materials. The conductive materials may include metal such as copper, aluminum, nickel, titanium, a combination thereof or other suitable metals. In some embodiments, the conductive features 164 are electrically connected to the redistribution layer 162 to form electrical connection between the package component 135 and the external environment.

Furthermore, a redistribution layer 172 is formed over the fourth insulating layer 160. The redistribution layer 172 may include conductive materials. The conductive materials may include metal such as copper, aluminum, nickel, titanium, a combination thereof or other suitable metals. In some embodiments, the redistribution layer 172 is electrically connected to the conductive features 164 to form electrical connection between the package component 135 and the external environment.

Moreover, a fifth insulating layer 170 is formed over the redistribution layer 172 and the fourth insulating layer 160. In some embodiments, the fifth insulating layer 170 includes polymers such as polybenzoxazoles (PBO), polyimide (PI), benzocyclobutene (BCB), or the like. The fifth insulating layer 170 may be formed, for example, by spin-on coating, chemical vapor deposition (CVD), physical vapor deposition (PVD) or other suitable deposition technique. However, the present disclosure is not limited thereto. In some other embodiments, the fourth insulating layer 160 includes dielectric materials, such as phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, the fifth insulating layer 170 may be formed by the same material and the same method as the first insulating layer 110, the second insulating layer 120, the third insulating layer 150, or the fourth insulating layer 160. However, the present disclosure is not limited thereto. In some embodiments, the fifth insulating layer 170 is formed by using material or method that is different from that of the first insulating layer 110 or the second insulating layer 120, the third insulating layer 150, or the fourth insulating layer 160.

Then, as shown in FIG. 1S, a plurality of under-bump metallization (UBM) structures 180 are formed through the fifth insulating layer 170 to the redistribution layer 172, and a plurality of bump structures 190 are formed over the UBM structures 180. The UBM structures 180 may include one or more layers of copper, nickel, gold, or the like, which are formed by a plating process, or the like. In some embodiments, the formation of the bump structures 190 may include placing solder balls on exposed portions of the UBM structures 180 and reflowing the solder balls. In some embodiments, the formation of the bump structures 190 includes performing a plating step to form solder regions over the UBM structures 180 and then reflowing the solder regions. However, the present disclosure is not limited thereto. In some embodiments, the bump structures 190 may include controlled collapse chip connection (C4) bumps, solder bumps, copper bumps, micro bumps, electroless nickel-electroless palladium-immersion gold technique (ENEPIG) formed bumps, ball grid array (BGA) bumps, copper pillars, or the like.

The UBM structures 180 and the bump structures 190 may be used to provide input/output connections to other electrical components, such as, other device dies, redistribution structures, printed circuit boards (PCBs), motherboards, or the like. The UBM structures 180 and the bump structures 190 may also be referred to as backside input/output pads that may provide signal, supply voltage, and/or ground connections to the package component 135 discussed above.

Next, as shown in FIG. 1T, the carrier substrate 102 is detached from the substrate 100. In some embodiments in which the release layer 101 is a light-to-heat-conversion (LTHC) coating layer, the release layer 101 may be exposed to light so that the release layer 101 is released from the substrate 100. As a result, a package structure 10 is formed. It should be noted that the package structure 10 may include other electronic components that are not shown in the present embodiments to achieve other functions. All the possible electronic components are contemplated within the scope of the present disclosure.

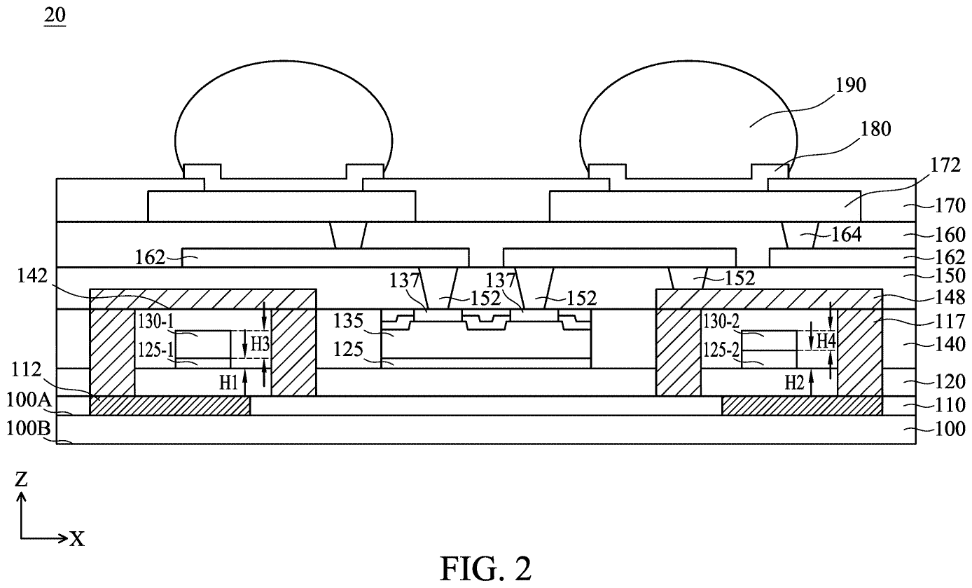

FIG. 2 is a cross-sectional view illustrating the package structure 20 in accordance with some embodiments of the present disclosure. It should be noted that the package structure 20 in the present embodiments may include the same or similar components as those of the package structure 10 shown in FIG. 1T. These components will be denoted by the same or similar numerals and will not be discussed in detail in the following paragraphs. As shown in FIG. 2, the package structure 20 includes a first magnetic element 130-1 bonded to the second insulating layer 120 via a first attach film 125-1. The package structure 20 also includes a second magnetic element 130-2 bonded to the second insulating layer 120 via a second attach film 125-2.

In some embodiments, the first attach film 125-1 has a height H1 and the second attach film 125-2 has a height H2. The first magnetic element 130-1 has a height H3 and the second magnetic element 130-2 has a height H4. For example, the height H3 of the first magnetic element 130-1 is different from the height H4 of the second magnetic element 130-2 since the number of the magnetic permeable layers in the first magnetic element 130-1 is different from the number of the magnetic permeable layers in the second magnetic element 130-2. In some embodiments, the sum of the heights H1 and H3 of the first attach film 125-1 and the first magnetic element 130-1 is substantially equal to the sum of the heights H2 and H4 of the second attach film 125-2 and the second magnetic element 130-2. In some embodiments, these heights H1, H2, H3, and H4 may be measured in the vertical direction (e.g. the Z direction) which is substantially perpendicular to the X-Y plane.

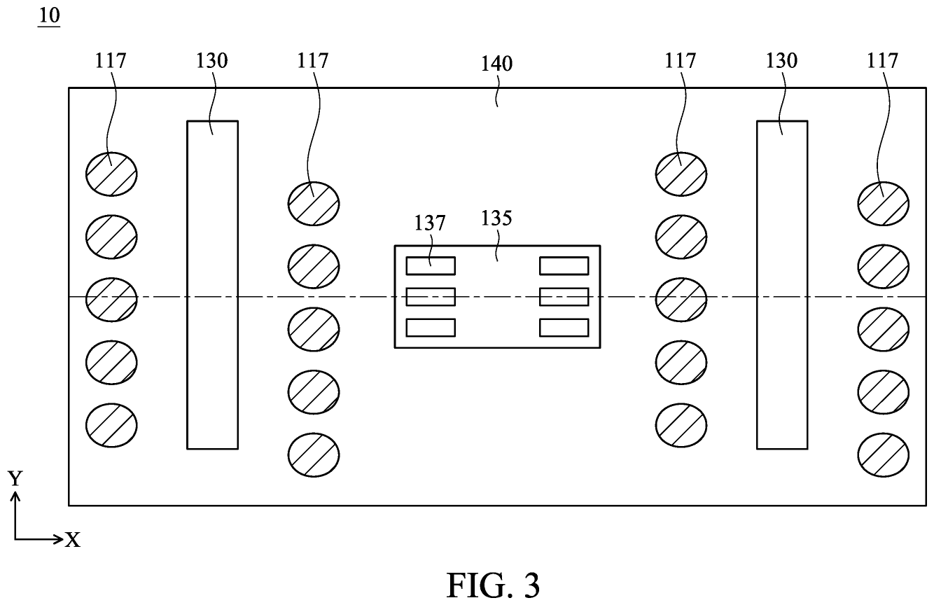

FIG. 3 is a schematic top view illustrating the package structure 10 in accordance with some embodiments of the present disclosure. As shown in FIG. 3, the package structure 10 includes the magnetic elements 130 on opposite sides of the package component 135. The conductive vias 117 are disposed around and spaced apart from the magnetic elements 130. In some other embodiments, the conductive vias 117 may each have a rounded profile in the top view. However, the present disclosure is not limited thereto. In some embodiments, the conductive vias 117 may have a radius from about 10 μm to about 20 μm, such as about 15 μm. The magnetic element 130 is laterally separated from the conductive vias 117 by the molding material 140. In some embodiments, the distance between the conductive via 117 and the adjacent magnetic element 130 may be ranged from about 5 μm to about 15 μm, such as about 10 μm. For example, the distance between the conductive via 117 and the adjacent magnetic element 130 may be the minimum distance from the outer edge of the conductive via 117 to the outer edge of the magnetic element 130.

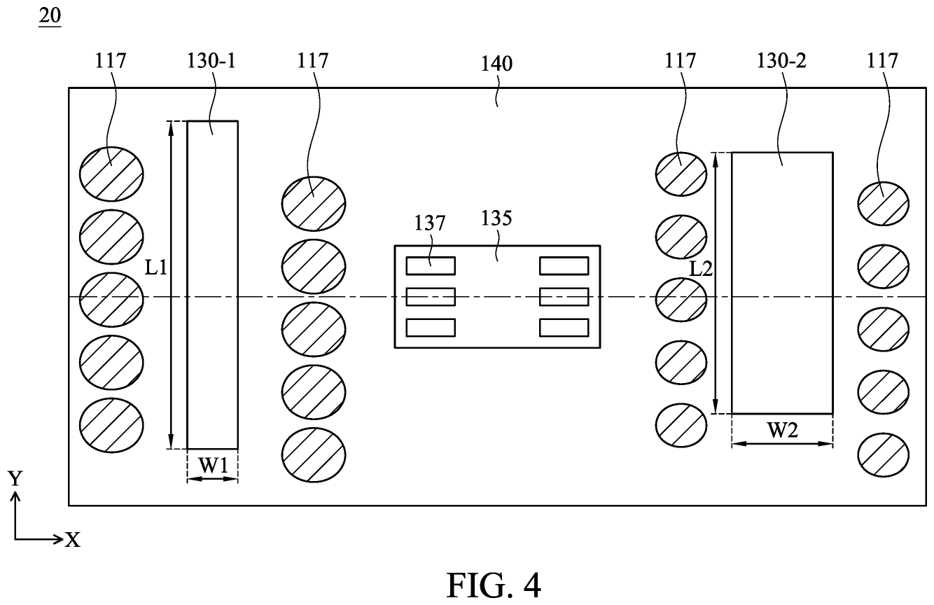

FIG. 4 is a schematic top view illustrating the package structure 20 in accordance with some embodiments of the present disclosure. As shown in FIG. 4, the package structure 20 includes the first magnetic element 130-1 and the second magnetic element 130-2 on opposite sides of the package component 135. The conductive vias 117 are disposed around and spaced apart from the first magnetic element 130-1 and the second magnetic element 130-2. In some other embodiments, the conductive vias 117 may each have a rounded profile in the top view. However, the present disclosure is not limited thereto. In some embodiments, the first magnetic element 130-1 may have a first length L1 and a first width W1, and the second magnetic element 130-2 may have a second length L2 and a second width W2. For example, the first length L1 may be greater than the second length L2, and the first width W1 may be less than the second width W2. In some embodiments, the first length L1 and the second length L2 may be measured in the Y direction, and the first width W1 and the second width W2 may be measured in the X direction. However, the present disclosure is not limited thereto. In some embodiments, the number of the magnetic permeable layers in the first magnetic element 130-1 is different from the number of the magnetic permeable layers in the second magnetic element 130-2. For example, the number (e.g. 28) of the magnetic permeable layers in the second magnetic element 130-2 may be four times the number (e.g. 7) of the magnetic permeable layers in the first magnetic element 130-1. However, the present disclosure is not limited thereto.

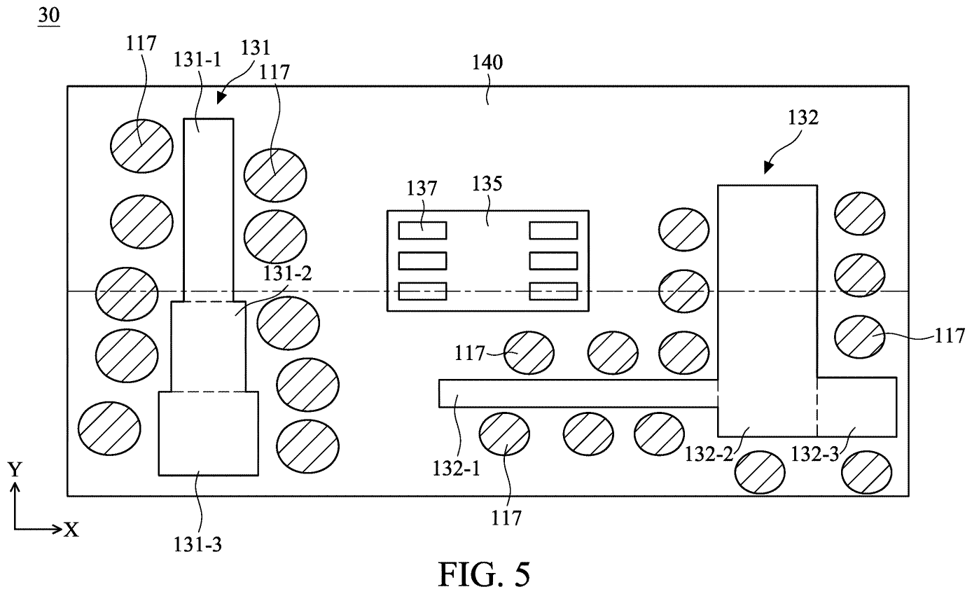

FIG. 5 is a schematic top view illustrating the package structure 30 in accordance with some embodiments of the present disclosure. It should be noted that the package structure 30 in the present embodiments may include the same or similar components as those of the package structure 10 shown in FIG. 1T. These components will be denoted by the same or similar numerals and will not be discussed in detail in the following paragraphs. As shown in FIG. 5, the package structure 30 includes a first magnetic element 131 and a second magnetic element 132 on opposite sides of the package component 135. In some embodiments, the first magnetic element 131 includes a first portion 131-1, a second portion 131-2, and a third portion 131-3 that are connected to each other. The interface among the first portion 131-1, the second portion 131-2, and the third portion 131-3 may be shown as dotted lines. The widths of the first portion 131-1, the second portion 131-2, and the third portion 131-3 are different from each other. For example, the width of the first portion 131-1 may be ranged from about 5 μm to about 15 μm, such as about 10 μm. The width of the second portion 131-2 may be ranged from about 10 μm to about 20 μm, such as about 15 μm. The width of the third portion 131-3 may be ranged from about 15 μm to about 25 μm, such as about 20 μm. However, the present disclosure is not limited thereto. It should be noted that the widths of the first portion 131-1, the second portion 131-2, and the third portion 131-3 may be measured in the X direction, for example.

In addition, the second magnetic element 132 includes a first portion 132-1, a second portion 132-2, and a third portion 132-3 that are connected to each other. The interface among the first portion 132-1, the second portion 132-2, and the third portion 132-3 may be shown as dotted lines. The shapes of the first portion 132-1, the second portion 132-2, and the third portion 132-3 are different from each other. As a result, a regular or irregular profile may be formed for the second magnetic element 132. For example, the profile of the second magnetic element 132 may be polygonal. However, the present disclosure is not limited thereto.

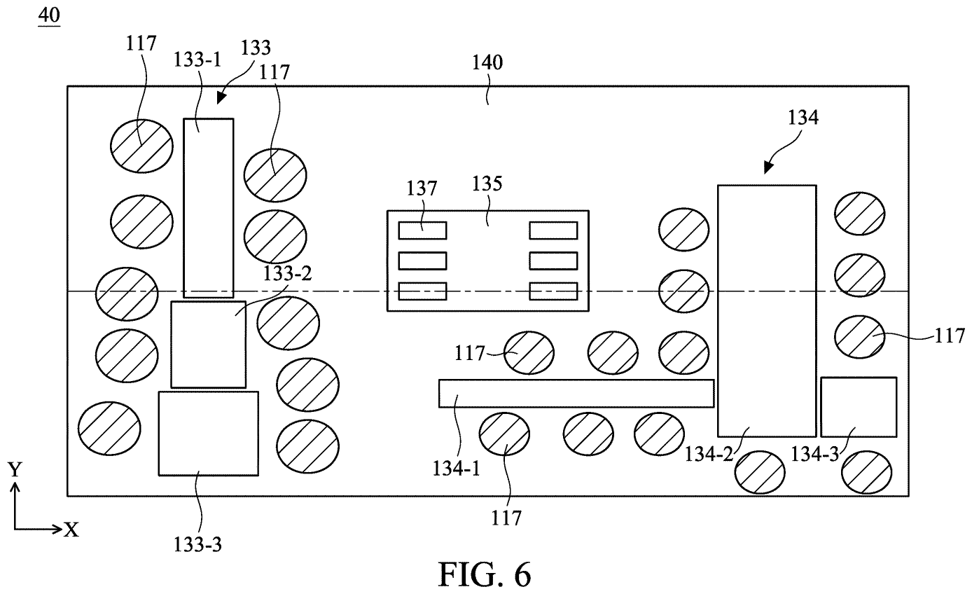

FIG. 6 is a schematic top view illustrating the package structure 40 in accordance with some embodiments of the present disclosure. It should be noted that the package structure 40 in the present embodiments may include the same or similar components as those of the package structure 30 shown in FIG. 5. These components will be denoted by the same or similar numerals and will not be discussed in detail in the following paragraphs. As shown in FIG. 6, the package structure 40 includes a first magnetic element 133 and a second magnetic element 134 on opposite sides of the package component 135. In some embodiments, the first magnetic element 133 includes a first portion 133-1, a second portion 133-2, and a third portion 133-3 that are spaced apart from each other. Similarly, the widths of the first portion 133-1, the second portion 133-2, and the third portion 133-3 are different from each other. For example, the width of the first portion 133-1 may be ranged from about 5 μm to about 15 μm, such as about 10 μm. The width of the second portion 133-2 may be ranged from about 10 μm to about 20 μm, such as about 15 μm. The width of the third portion 133-3 may be ranged from about 15 μm to about 25 μm, such as about 20 μm. However, the present disclosure is not limited thereto. It should be noted that the widths of the first portion 131-3, the second portion 133-2, and the third portion 133-3 may be measured in the X direction, for example.

In addition, the second magnetic element 134 includes a first portion 134-1, a second portion 134-2, and a third portion 134-3 that are spaced apart from each other. The shapes of the first portion 134-1, the second portion 134-2, and the third portion 134-3 are different from each other. As a result, a regular or irregular profile may be formed for the second magnetic element 134. However, the present disclosure is not limited thereto.

FIG. 7 is a cross-sectional view illustrating the magnetic element 130 in accordance with some embodiments of the present disclosure. As shown in FIG. 7, the magnetic element 130 includes a plurality of dielectric layers 136-1 to 136-9 and a plurality of magnetic permeable layers 138-1 to 138-8 that are alternatively stacked. In some embodiments, the magnetic element 130 is attached to the second insulating layer 120 via the attach film 125. The dielectric layer 136-1 is disposed on the attach film 125, and the magnetic permeable layer 138-1 is disposed on the dielectric layer 136-1. Similarly, the dielectric layer 136-2 is disposed on the magnetic permeable layers 138-1, and the magnetic permeable layer 138-2 is disposed on the dielectric layer 136-2. For example, the dielectric layers 136-1 to 136-9 may include epoxy or any other suitable adhesive material to bond the stacked magnetic permeable layers 138-1 to 138-8. However, the present disclosure is not limited thereto.

In some embodiments, the magnetic permeable layers 138-1 to 138-8 may have a first thickness T1, and the dielectric layers 136-1 to 136-9 may have a second thickness T2. The first thickness T1 may be different from the second thickness T2. In some embodiments, the second thickness T2 greater than the first thickness T1. For example, the first thickness T1 may be from about 20 μm to about 0.01 μm, such as about 5 μm. The second thickness T2 may be from about 50 μm to about 0.1 μm, such as about 21 μm. However, the present disclosure is not limited thereto.

In some embodiments, the number of the magnetic permeable layers in the magnetic element 130 is greater than or equal to 2 and less than or equal to 40. For example, the number of the magnetic permeable layers in the magnetic element 130 is greater than or equal to 7 and less than or equal to 40. However, the present disclosure is not limited thereto. Since the magnetic element 130 includes a plurality of magnetic permeable layers (e.g. 138-1 to 138-8) that are separated from each other by dielectric layers (e.g. 136-1 to 136-9), eddy current induced by the inductor may be reduced, improving the performance of the inductor.

In some embodiments, the conductive feature 112 is electrically connected to the conductive via 117 through the via 121 in the second insulating layer 120. Similarly, the conductive feature 148 is electrically connected to the conductive via 117 through the via 151 in the third insulating layer 150. As a result, a coil 149 may be formed around the magnetic element 130, forming a inductor in the resulting package structure to enhance the performance of the devices. In some embodiments, the molding material 140 is sandwiched between the magnetic element 130 (e.g. the dielectric layer 136-9) and the third insulating layer 150 in the vertical direction (e.g. the Z direction) which are perpendicular to the top surface of the substrate 100. Accordingly, the magnetic element 130 is electrically isolated from the coil 149.

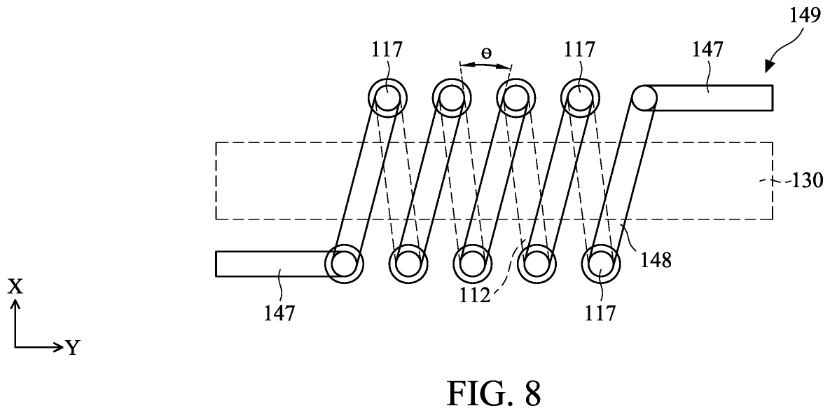

FIG. 8 is a schematic plan view illustrating the magnetic element 130 and the coil 149 in accordance with some embodiments of the present disclosure. As shown in FIG. 8, the magnetic element 130 is surrounded by the coil 149. To be more specific, the coil 149 includes conductive lines 147, conductive features 148, conductive vias 117, and conductive features 112 that are electrically connected to each other, and therefore the coil 149 has four turns around the magnetic element 130. In some embodiments, an angle θ is formed between the adjacent conductive features 112 and 148, and the angle θ may be ranged from about 2° to about 88°, for example.

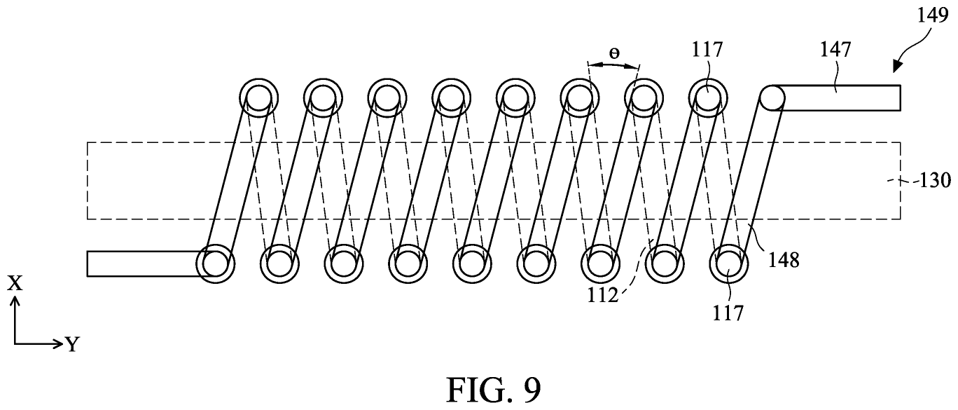

FIG. 9 is a schematic plan view illustrating the magnetic element 130 and the coil 149 in accordance with some embodiments of the present disclosure. It should be noted that the magnetic element 130 and the coil 149 in the present embodiments may include the same or similar components as those of the magnetic element 130 and the coil 149 shown in FIG. 8. These components will be denoted by the same or similar numerals and will not be discussed in detail in the following paragraphs. As shown in FIG. 9, the coil 149 has eight turns around the magnetic element 130. It is appreciated that the number of turns of the coil 149 around the magnetic element 130 has a positive correlation with the inductance value of the resulted inductor. For example, the number of turns of the coil 149 around the magnetic element 130 is proportional to the inductance value of the resulted inductor.

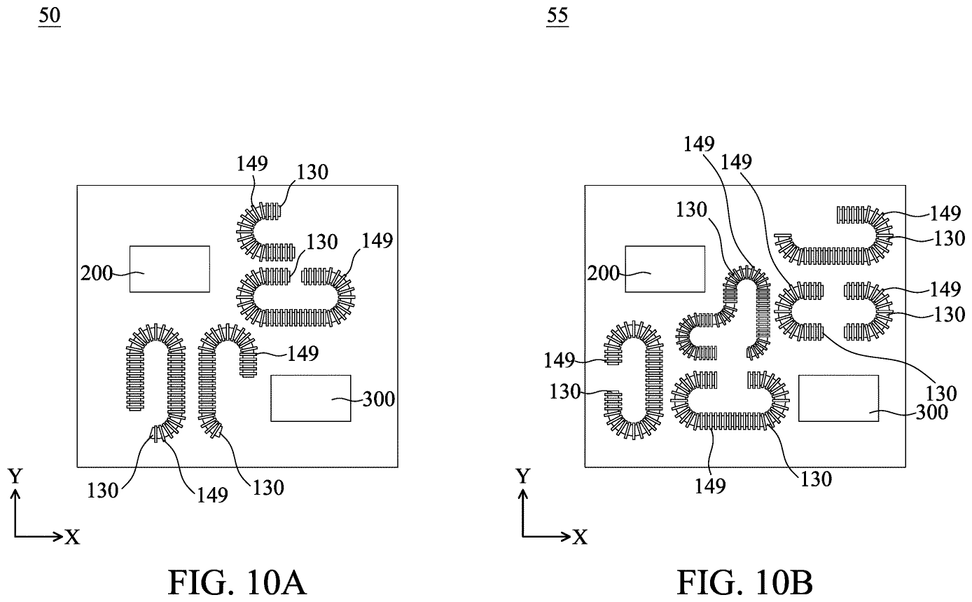

FIG. 10A-10B are schematic plan views illustrating the package structures 50 and 55 in accordance with some embodiments of the present disclosure. As shown in FIG. 10A-10B, the package structures 50 and 55 each include an integrated circuit 200 and a device die 300. For example, the integrated circuit 200 may be a power management integrated circuit (PMIC), and the device die 300 may be a System-on-Chip (SoC) die including a plurality of device dies packaged as a system. For example, the device die 300 may be or may include logic dies, memory dies, input-output dies, Integrated Passive Devices (IPDs), or the like, or combinations thereof. For example, the logic device dies may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies may include Static Random Access Memory (SRAM) dies, Dynamic Random Access Memory (DRAM) dies, or the like.

In some embodiments, the integrated circuit 200 and the device die 300 are electrically connected to the inductors that are formed by the magnetic elements 130 and the coils 149. For example, the inductors may be disposed in any space around the integrated circuit 200 and the device die 300. Accordingly, the freedom and the diversity for designing the overall layout may be improved. To be more specific, the magnetic elements 130 may be curved, but not form a closed loop. In some embodiments, the magnetic element 130 (and the coils 149) in one inductor may be divided into multiple sections that are separated from each other. In this way, it is less likely that the inductances generated in each section of the inductor would be interfered with each other, which reduce the performance of the inductor. As a result, the inductance value of the inductors that are formed by the magnetic elements 130 and the coils 149 may be increased, improving the performance of the resulted inductors. Moreover, the curved or separated arrangement of the inductor may utilize the space of the package structures 50 and 55 more efficiency, and therefore the redundant space of the package structures 50 and 55 may be reduced.

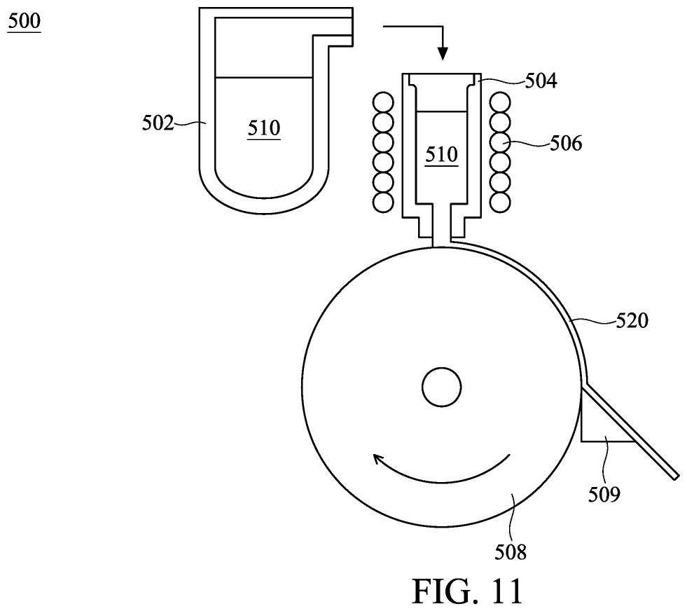

FIG. 11 is a schematic view illustrating an apparatus 500 for forming a magnetic permeable layer 520 in accordance with some embodiments of the present disclosure. As shown in FIG. 11, the apparatus 500 includes a storage tank 502 that stores a raw material 510 of the magnetic permeable layer 520. In some embodiments, the raw material 510 includes liquid metal, such as Fe, Co, Ni, Nb, Si, B, or an alloy thereof. In some embodiments, the raw material 510 may be stored at a temperature about 1300 °C. However, the present disclosure is not limited thereto.

Then, the raw material 510 is transferred to a container 504 that is surrounded by a coil 506. In some embodiments, the coil 506 is turned on to heat up the raw material 510 inside the container 504, so as to keep the raw material 510 in a liquid state. In some embodiments, the raw material 510 may flow out of the container 504 and arrive onto a casting wheel 508. The casting wheel 508 rotates to spin the raw material 510 and operates at a temperature about 10 °C. However, the present disclosure is not limited thereto. As a result, the raw material 510 may be cooled down rapidly and forms the magnetic permeable layer 520. The apparatus 500 includes a stopper 509 for removing the magnetic permeable layer 520 from the casting wheel 508. It should be noted that the resulted magnetic permeable layer 520 is applicable in any of the magnetic elements discussed in the present disclosure. In some embodiments, the magnetic permeability of the magnetic permeable layers 520 is ranged from about 1,000 nH to about 1,000,000 nH. The magnetic permeability of the resulted magnetic permeable layers 520 varies based on the element composition of the raw material 510.

As described above, the present disclosure is directed to package structures and methods for forming the same. The package structure includes at least one inductor that is formed by a magnetic element surrounded by a coil. The inductor operates along with the package component (e.g. devices) in the package structure so as to reduce signal interference or stabilize the voltage of the devices. In addition, the inductor formed by the magnetic element and the coil is embedded in the molding material along with the package component, which is compatible with the current package process, and therefore reducing the time and cost of the overall process. Furthermore, the magnetic element includes a plurality of magnetic permeable layers that are separated from each other by dielectric layers. Accordingly, eddy current induced by the inductor may be reduced, improving the performance of the inductor.

In accordance with some embodiments, a package structure is provided and includes a first insulating layer, a second insulating layer, a magnetic element, a molding material, and a third insulating layer. The first insulating layer is formed on a substrate, and a first conductive feature is formed in the first insulating layer. The second insulating layer is formed on the first insulating layer. The magnetic element is disposed on the second insulating layer and includes a plurality of dielectric layers and magnetic permeable layers that are alternatively stacked. The molding material covers the magnetic element and the conductive feature, and conductive vias penetrate the second insulating layer and the molding material. The third insulating layer is formed on the molding material, and a second conductive feature is formed in the third insulating layer. The first conductive feature, the conductive vias, and the second conductive feature are electrically connected to form a coil surrounding the magnetic element.

In accordance with some embodiments, a method of forming a package structure is provided and includes forming a first conductive feature in a first insulating layer. The method includes forming a second insulating layer on the first insulating layer. The second insulating layer covers the first conductive feature. The method includes disposing a magnetic element on the second insulating layer. The magnetic element comprises a plurality of dielectric layers and a plurality of magnetic permeable layers, and the dielectric layers and the magnetic permeable layers are alternatively stacked. The method includes forming a molding material covering the magnetic element. A plurality of conductive vias penetrate the second insulating layer and the molding material. The method also includes forming a second conductive feature in a third insulating layer on the molding material. The first conductive feature, the conductive vias, and the second conductive feature are electrically connected to form a coil surrounding the magnetic element.

In accordance with some embodiments, a package structure is provided and includes a first insulating layer, a second insulating layer, a first magnetic element, a second magnetic element, a molding material, and a third insulating layer. The first insulating layer is formed on a substrate. A first plurality and a second plurality of first conductive features are formed in the first insulating layer. The second insulating layer is formed on the first insulating layer. The first magnetic element and the second magnetic element are disposed on the second insulating layer. The width of the first magnetic element is different from the width of the second magnetic element in the direction parallel to the top surface of the substrate. The molding material covers the magnetic element. The first plurality and the second plurality of conductive vias penetrate the second insulating layer and the molding material. The third insulating layer is formed on the molding material. A first plurality and a second plurality of second conductive features are formed in the third insulating layer. The first plurality of first conductive features, the first plurality of conductive vias, and the first plurality of the second conductive feature are electrically connected to form a first coil surrounding the first magnetic element, the second plurality of first conductive features, the second plurality of conductive vias, and the second plurality of the second conductive feature are electrically connected to form a second coil surrounding the second magnetic element.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a package structure, comprising:
forming a first conductive feature in a first insulating layer;
forming a second insulating layer on the first insulating layer, wherein the second insulating layer covers the first conductive feature;
disposing a magnetic element on the second insulating layer, wherein the magnetic element comprises a plurality of dielectric layers and a plurality of magnetic permeable layers, and the dielectric layers and the magnetic permeable layers are alternatively stacked;
forming a molding material covering the magnetic element, wherein a plurality of conductive vias penetrate the second insulating layer and the molding material; and
forming a second conductive feature in a third insulating layer on the molding material, wherein the first conductive feature, the conductive vias, and the second conductive feature are electrically connected to form a coil surrounding the magnetic element.

2. The method as claimed in claim 1, further comprising:
disposing a package component on the second insulating layer, wherein the package component is disposed when disposing the magnetic element.

3. The method as claimed in claim 1, wherein the conductive vias are formed prior to forming the second insulating layer on the first insulating layer.

4. The method as claimed in claim 1, further comprising:
forming the magnetic element prior to disposing the magnetic element on the second insulating layer.

5. The method as claimed in claim 4, wherein forming the magnetic element further comprises forming the magnetic permeable layers by cooling down a liquid metal material and spinning the liquid metal material around a casting wheel.

6. A method of forming a package structure, comprising:
forming a first conductive feature in a first insulating layer on a substrate;
forming a second insulating layer on the first insulating layer and the first conductive feature;
disposing a magnetic element on the second insulating layer, wherein the magnetic element comprises a plurality of portions spaced apart from each other and arranged in a first direction;
forming a molding material over the magnetic element and the first conductive feature;
forming a plurality of conductive vias through the second insulating layer and the molding material, wherein the conductive vias are electrically connected to the first conductive feature, and a spacing between the conductive vias on opposite sides of the magnetic element increases along the first direction;
forming a third insulating layer on the molding material; and
forming a second conductive feature in the third insulating layer, wherein the second conductive feature is electrically connected to the conductive vias.

7. The method as claimed in claim 6, further comprising:
disposing a package component on the second insulating layer, wherein the package component is electrically isolated from the magnetic element, and the molding material is laterally sandwiched between the conductive vias and the package component.

8. The method as claimed in claim 7, wherein a top surface of the second conductive feature is higher than a top surface of the package component, and a top surface of the first conductive feature is lower than a bottom surface of the package component.

9. The method as claimed in claim 7, further comprising:
disposing an additional magnetic element on the second insulating layer, wherein the additional magnetic element comprises a plurality of portions spaced apart from each other and arranged in a second direction perpendicular to the first direction;

10. The method as claimed in claim 9, wherein the package component is located between the magnetic element and the additional magnetic element.

11. The method as claimed in claim 6, wherein widths of the portions of the magnetic element increases along the first direction.

12. The method as claimed in claim 6, wherein a height of the conductive vias i greater that a height of the magnetic element.

13. A method of forming a package structure, comprising:
forming a first conductive feature in a first insulating layer on a substrate;
forming a second insulating layer on the first insulating layer and the first conductive feature;
disposing a first magnetic element on the second insulating layer, wherein the first magnetic element comprises a first portion extending in a first direction and a second portion extending in a second direction perpendicular to the first direction;
forming a molding material over the magnetic element and the first conductive feature;
forming a plurality of conductive vias through the second insulating layer and the molding material, wherein the conductive vias are electrically connected to the first conductive feature, and located on opposite sides of the first portion and the second portion;
forming a third insulating layer on the molding material; and
forming a second conductive feature in the third insulating layer, wherein the second conductive feature is electrically connected to the conductive vias.

14. The method as claimed in claim 13, wherein the first portion is connected to the second portion.

15. The method as claimed in claim 13, further comprising:
a second magnetic element disposed on the second insulating layer, wherein the second magnetic element is vertically separated from the first conductive feature by the second insulating layer.

16. The method as claimed in claim 15, wherein a width of the first magnetic element is different from a width of the second magnetic element in the first direction or the second direction.

17. The method as claimed in claim 15, further comprising:
disposing a first attach film to bond the first magnetic element to the second insulating layer; and
disposing a second attach film to bond the second magnetic element to the second insulating layer.

18. The method as claimed in claim 17, wherein a height of the first attach film is different from a height of the second attach film in a third direction perpendicular to the first direction and the second direction.

19. The method as claimed in claim 13, further comprising:
disposing a package component on the second insulating layer, wherein the first portion is located on a first side of the package component, and the second portion is located on a second side of the package component.

20. The method as claimed in claim 19, wherein a first one of the conductive vias is sandwiched between the package component and the first magnetic element in the first direction, and a second one of the conductive vias is sandwiched between the package component and the first magnetic element in the second direction.
